(19) United States
(12) Patent Application Publication
(10) Pub. No.: US 2012/0007213 A1
(43) Pub. Date: Jan. 12, 2012

(54) SEMICONDUCTOR CHIP AND METHOD FOR FABRICATING THE SAME

(75) Inventors: Hyeong Seok CHOI, Seoul (KR); Jin Hui LEE, Icheon-si (KR)

(73) Assignee: HYNIX SEMICONDUCTOR INC., Icheon-si (KR)

(21) Appl. No.: 13/118,786

(22) Filed: May 31, 2011

(30) Foreign Application Priority Data
Jul. 7, 2010 (KR) 10-2010-0065589

(51) Int. Cl. H01L 23/525; H01L 21/82

(52) U.S. Cl. 257/529; 438/132; 257/E23.149; 257/E21.602

(57) ABSTRACT

A semiconductor chip includes: a semiconductor substrate in which a bonding pad is provided on a first surface thereof; a through silicon via (TSV) group including a plurality of TSVs connected to the bonding pad and exposed to a second surface opposite to the first surface of the semiconductor substrate; and a fuse box including a plurality of fuses connected to the plurality of TSVs and formed on the first surface of the semiconductor substrate.

### CROSS-REFERENCES TO RELATED APPLICATIONS

The present application claims priority under 35 U.S.C 119(a) to Korean Application No. 10-2010-0065589, filed on Jul. 7, 2010 in the Korean intellectual property Office, which is incorporated herein by reference in its entirety.

### BACKGROUND

Exemplary embodiments of the present invention relate to a semiconductor chip and a method for fabricating the same, and more particularly, to a wafer level package having through silicon vias (TSVs) and a method for fabricating the same.

Among various techniques for stacking semiconductor integrated circuits, a three-dimensional stack technique has been developed to reduce the size of the electronic components, increase the packaging density thereof, and improve the performance thereof. Such a three-dimensional stack package is generally called a stack chip package and is fabricated by stacking a plurality of chips that have the same storage capacity. The stack chip package technique uses a simplified process that is cost effective for mass production. However, due to the increase in the number and the size of chips being stacked, the interconnection space for electrical connection inside the package is insufficient. Generally, the existing stack chip package is fabricated so that a bonding pad of each chip and a conductive circuit pattern of a substrate are electrically conducted through a wire such that a plurality of chips are attached in a chip bonding area of the substrate. Therefore, the existing stack chip package requires a space for wire bonding and a circuit pattern area of the substrate to which the wires are connected, which will cause the increase in the size of a semiconductor package. Accordingly, much attention has recently been paid to a structure using through silicon vias (TSVs). In this structure, TSVs are formed within chips at a wafer level and are used to electrically connect the chips.

FIG. 1 is a flowchart illustrating a method for fabricating a semiconductor chip having TSVs. Referring to FIG. 1, semiconductor devices are formed in a semiconductor substrate at step 110. The semiconductor devices may be semiconductor memory devices, semiconductor logic devices, or semiconductor power devices. In some cases, passive elements may be formed together with the semiconductor devices. At step 120, a fuse repair is performed to repair a defective interconnection. A wafer test process may be performed to detect the defective interconnection prior to the fuse repair. At step 130, TSVs are formed. The TSVs may be formed by forming via holes which pass through the semiconductor substrate and expose bonding pads, and filling the via holes with a metal film. At step 140, a wafer level package is formed by vertically stacking the wafers that have the TSVs.

In such a fabrication process, however, since one TSV is connected to one pad, a defective TSV cannot be repaired when the TSV is not formed appropriately. For example, a TSV may not be formed appropriately when a bonding pad is opened because the via hole is not completely filled with the metal film. Moreover, since the test is performed by stacking wafers vertically after the wafer level package is fabricated, all chips stacked in the wafer level package are discarded when any one of the chips is determined as a defective chip in the test result. Accordingly, the productivity of the wafer level package is lowered. In addition, since the fuse repair has already been performed before the formation of TSVs, a defective interconnection detected after the formation of the TSVs cannot be repaired.

### SUMMARY

An embodiment of the present invention is directed to a semiconductor chip where a defective TSV or a defective interconnection can be repaired even after formation of TSVs, and a method for fabricating the same.

In one embodiment, a semiconductor chip includes: a semiconductor substrate in which a bonding pad is provided on a first surface thereof; a through silicon via (TSV) group including a plurality of TSVs connected to the bonding pad and exposed to a second surface opposite to the first surface of the semiconductor substrate; and a fuse box including a plurality of fuses, which are connected to the plurality of TSVs, formed on the first surface of the semiconductor substrate.

Only one of the plurality of TSVs may be electrically connected to the bonding pad. In this case, the TSV electrically connected to the bonding pad may be electrically connected to the bonding pad through any one of the plurality of fuses.

The fuse box may be exposed through a via hole in the semiconductor substrate.

The plurality of fuses may be exposed through a plurality of holes in the semiconductor substrate.

The semiconductor chip may further include a redistribution layer which connects the bonding pad to the plurality of TSVs.

In another embodiment, a method for fabricating a semiconductor chip includes: preparing a wafer including a plurality of semiconductor chips, each of which includes a bonding pad on a first surface of the wafer and a fuse box including a plurality of fuses connected to the bonding pad; forming a TSV group including a plurality of TSVs, which are connected to the plurality of fuses, exposed to a second surface opposite to the first surface of the semiconductor substrate; and performing a repair process to select any one of the plurality of TSVs.

The forming of the TSV group may include: forming an insulation layer which exposes the bonding pad on the first surface of the wafer; attaching the wafer to a carrier to expose the second surface opposite to the first surface of the wafer; forming a plurality of blind via holes from the second surface of the wafer; and forming a plurality of TSVs in the plurality of blind via holes.

The forming of the TSV group may further include forming a via hole exposing the plurality of fuses to the second surface of the wafer.

The forming of the via hole may be performed by forming a via hole exposing the entire fuse box.

The forming of the via hole may be performed by forming a plurality of holes exposing the plurality of fuses separately.

The forming of the via hole may be performed simultaneously with the forming of the blind via holes.

The repair process may be performed by cutting one or more of the plurality of fuses exposed by the via hole.

### BRIEF DESCRIPTION OF THE DRAWINGS

The above and other aspects, features and other advantages will be more clearly understood from the following detailed description taken in conjunction with the accompanying drawings, in which:

FIG. 1 is a flowchart that schematically illustrates a conventional method for fabricating a semiconductor chip having TSVs;

FIG. 2 is a top plan view of a semiconductor chip according to an embodiment of the present invention;

FIG. 3 is a cross-sectional view taken along line III-III of FIG. 2;

FIG. 4 is a flowchart that schematically illustrates a method for fabricating a semiconductor chip according to an embodiment of the present invention; and

FIGS. 5 to 8 are detailed cross-sectional views illustrating some steps of FIG. 4 according to an embodiment of the present invention.

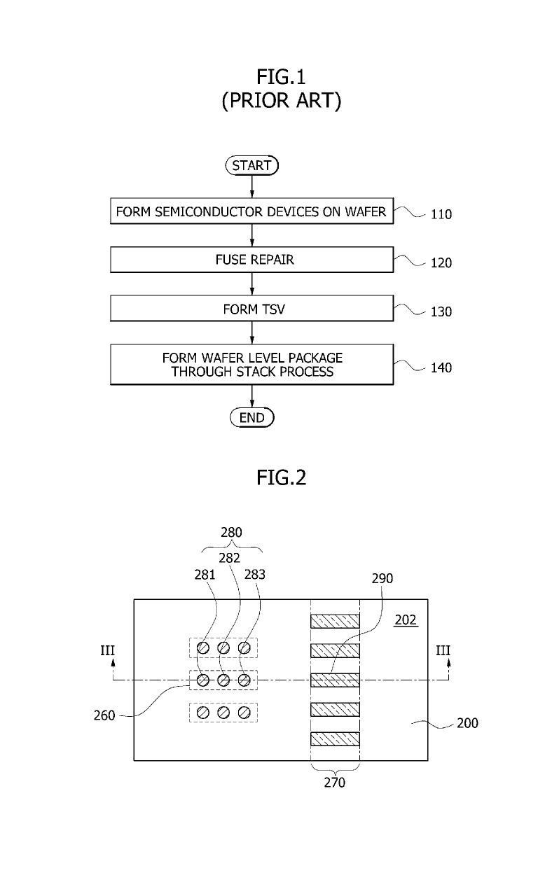

### DESCRIPTION OF SPECIFIC EMBODIMENTS

Hereinafter, embodiments of the present invention will be described with reference to accompanying drawings. However, the embodiments are for illustrative purposes only and are not intended to limit the scope of the invention.

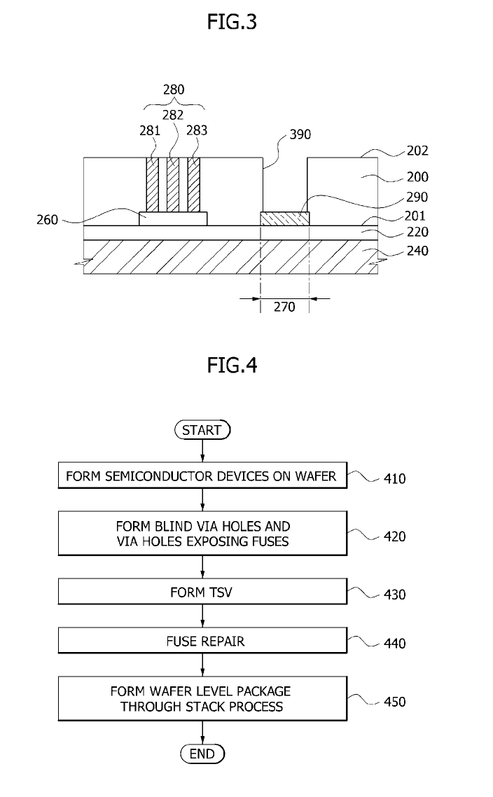

Referring to FIGS. 2 and 3, a semiconductor chip according to an embodiment of the present invention includes a semiconductor substrate 200, a bonding pad 260, a TSV group 280, and a fuse box 270. The semiconductor substrate 200 has a first surface 201 and a second surface 202 opposite to each other. The bonding pad 260 is disposed on the first surface 201 of the semiconductor substrate 200. The TSV group 280 includes a plurality of TSVs 281, 282 and 283 which are connected to the bonding pad 260 and exposed to the second surface 202 of the semiconductor substrate 200. The fuse box 270 includes a plurality of fuses 290 formed on the first surface 201 of the semiconductor substrate 200, and which are connected to the plurality of TSVs 281, 282 and 283. Although not illustrated, active elements and/or passive elements may be formed on the semiconductor substrate 200, and the bonding pad 260 and the fuses 290 may be electrically connected to the active elements and/or the passive elements. In addition, a passivation layer (not illustrated) having openings exposing the bonding pad 260 and the fuses 290 may be disposed on the first surface 201 of the semiconductor substrate 200.

A temporary substrate 240 is attached to the first surface 201 of the semiconductor substrate 200 through an adhesive layer 220. The temporary substrate 240 is temporarily attached to facilitate handling of the semiconductor substrate 200. The temporary substrate 240 may be formed of, for example, glass or silicon. In order to easily remove the temporary substrate 240 later as needed, the adhesive layer 220 is formed of a material whose adhesive strength can be reduced through a simple process such as, for example, UV irradiation.

The bonding pad 260 is electrically connected to any one of the plurality of TSVs constituting the conductive TSV group 280, that is, the first TSV 281, the second TSV 282, and the third TSV 283. The first TSV 281, the second TSV 282, and the third TSV 283 pass through the semiconductor substrate 200 and are disposed to be spaced apart from one another. The connection between the bonding pad 260 and the TSV 281, 282 or 283 is achieved through the plurality of fuses 290. In some cases, one or more TSVs may be electrically connected to the single bonding pad 260. The first TSV 281, the second TSV 282, and the third TSV 283 are generally formed of a metal film; however, the invention is not limited thereto. For example, the first TSV 281, the second TSV 282, and the third TSV 283 may be formed of any conductive film having a low resistance. Although not illustrated, the bonding pad 260 and the plurality of TSVs 281, 282 and 283 may be connected together through a redistribution layer.

The fuse box 270 begins from the second surface 202 of the semiconductor substrate 200 and is exposed in a downward direction of the semiconductor substrate 200 through a via hole 390 that passes through the semiconductor substrate 200. In some cases, the plurality of fuses 290 inside the fuse box 270 may be exposed in a downward direction of the semiconductor substrate 200 through a plurality of holes. One of the plurality of fuses 290 exposed by the via hole 390 is used to select one of the plurality of TSVs, the first TSV 281, the second TSV 282, and the third TSV 283, through a general fuse repair process. In some cases, a plurality of TSVs may be selected.

As one example, when the first TSV 281 and the second TSV 282 are defective and the third TSV 283 is not defective, the first TSV 281 and the second TSV 282 are not electrically connected to the bonding pad 260 through fuse repair, but only the third TSV 283 is electrically connected to the bonding pad 260. In order to perform such a fuse repair, an interconnection structure for electrical connection and disconnection is formed earlier between the first, second and third TSVs 281, 282 and 283 and the plurality of fuses 290. In general, the interconnection structure is formed during the process of forming elements within the semiconductor substrate 200.

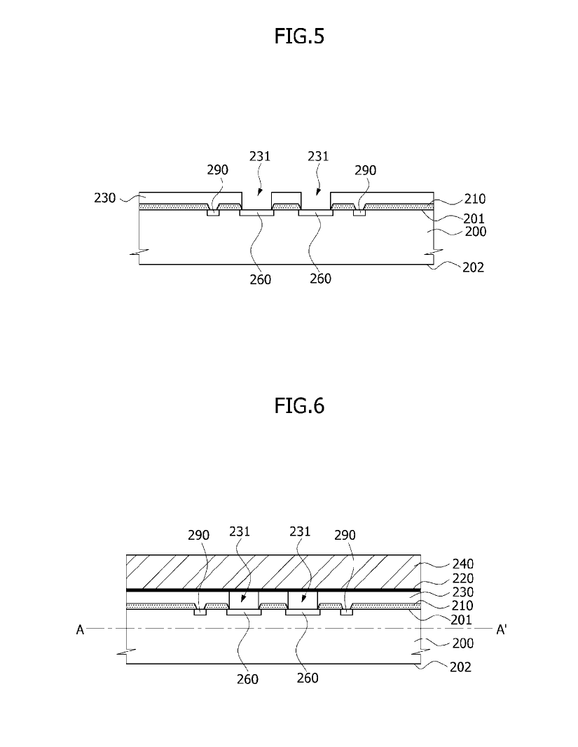

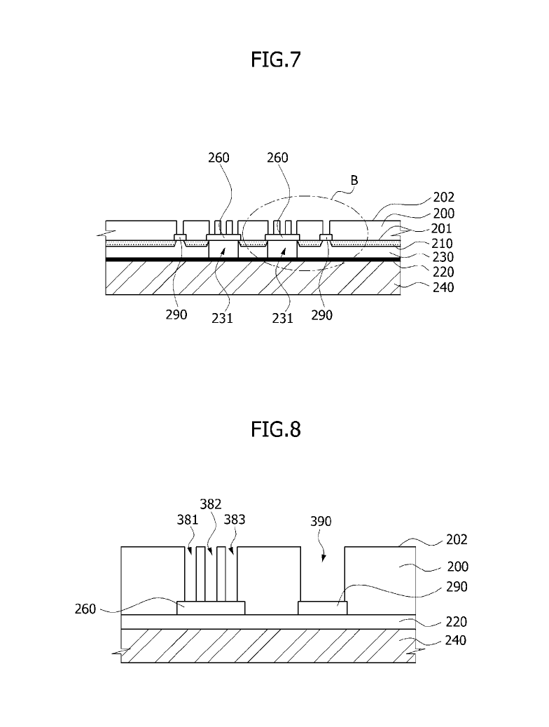

FIG. 4 is a flowchart illustrating a method for fabricating a semiconductor chip according to an embodiment of the present invention. FIGS. 5 to 8 are detailed cross-sectional views illustrating some steps of FIG. 4. Specifically, FIG. 8 is an enlarged view illustrating a portion “B” of FIG. 7. For simplicity, a passivation layer and an insulation layer of FIG. 7 are not illustrated in FIG. 8.

Referring to FIG. 4, semiconductor devices are formed in a plurality of semiconductor chips on a wafer at step 410. The semiconductor devices may be semiconductor memory devices, logic devices, or power devices. In some cases, passive elements may be formed together with the semiconductor devices. After the formation of the semiconductor devices, a bonding pad is formed on the surface thereof, and a fuse box is formed. The fuse box includes a plurality of fuses to be connected to the bonding pad. At step 420, blind via holes, which pass through the wafer to expose the bonding pad, and via holes, which pass through the wafer to expose the fuses, are formed.

The process of forming the blind via holes and the via holes will be described in more detail. As illustrated in FIG. 5, a wafer 200 has a first surface 201 and a second surface 202, and bonding pads 260 and fuses 290 are formed on the first surface 201 of the wafer 200. A passivation layer 210 having openings exposing the bonding pads 260 and the fuses 290 is formed on the first surface 201 of the wafer 200. The passivation layer 210 may be formed of nitride; however, the invention is not limited thereto. An insulation layer 230 is formed on the passivation layer 210. The insulation layer 230 has openings partially exposing the surface of the bonding pads 260. Therefore, although the fuses 290 are exposed by the passivation layer 210, they are covered by the insulation layer 230 on the passivation layer 210.

As illustrated in FIG. 6, a temporary wafer 240 is attached to the wafer 200 in which the insulation layer 210 is formed. The temporary wafer 240 is attached by an adhesive layer 220. The temporary wafer 240 is temporarily attached to facilitate handling of the semiconductor substrate 200. As one example, the temporary wafer 240 may facilitate handling of wafer 200 when the thickness of the wafer 200 is reduced by removing a portion under dotted lines A-A′ of FIG. 6.

As illustrated in FIGS. 7 and 8, a plurality of blind via holes 381, 382 and 383, which pass through the wafer 200 to expose the bonding pad 260, and a plurality of via holes 390, which pass through the wafer 200 to expose the plurality of fuses 290, are formed. The blind via holes 381, 382 and 383 and the via holes 390 may be formed simultaneously or separately. In order to form such via holes, a photoresist pattern is formed on the second surface 202 of the wafer 200, and then the bonding pads 260 and the fuses 290 are exposed by etching the exposed portions of the wafer 200 using the photoresist pattern as an etch mask. At this time, the via holes 390 may be formed to expose the fuse box 270, or the via holes 390 may be formed to expose the plurality of fuses separately.

After the formation of the blind via holes 381, 382 and 383 and the via holes 390, TSVs are formed by filling the blind via holes 381, 382 and 383 at step 430. Specifically, as illustrated in FIG. 3, the blind via holes 381, 382 and 383 exposing the bonding pad 260 are filled with a metal film to form the first TSV 281, the second TSV 282, and the third TSV 283. The filling of the metal film may be performed, for example, using an electroplating process after a metal seed is formed inside the blind via holes 381, 382 and 383.

At step 440, a fuse repair is performed on the fuses exposed by the via holes 390 in order to repair a defective interconnection. The fuse repair is performed by cutting one or more of the plurality of fuses 290 exposed by the via holes 390. Prior to the fuse repair, a wafer test process may be performed to detect the defective interconnection. During this process, the first TSV 281, the second TSV 282, and the third TSV 283 may also be tested. For example, as the test result, when the first TSV 281 and the second TSV 282 are determined to be defective, the fuses electrically connected to the first TSV 281 and the second TSV 282 are cut through a fuse repair to electrically disconnect the respective fuses from the TSVs 281 and 282. At step 450, after the fuse repair, a wafer level package is formed by stacking the wafers having the TSVs in a vertical direction.

According to various embodiments of the present invention, fuses and TSVs are formed at the same time, and the TSVs are formed to connect to a single bonding pad. The TSVs are selected through a fuse repair. Hence, a defective interconnection and a defective TSV can be repaired even after the formation of the TSVs.

The embodiments of the present invention have been disclosed above for illustrative purposes. Those skilled in the art will appreciate that various modifications, additions and substitutions are possible, without departing from the scope and spirit of the invention as disclosed in the accompanying claims.

What is claimed is:

1. A semiconductor chip comprising:
a semiconductor substrate in which a bonding pad is provided on a first surface thereof;
a through silicon via (TSV) group including a plurality of TSVs connected to the bonding pad and exposed to a second surface opposite to the first surface of the semiconductor substrate; and
a fuse box including a plurality of fuses, which are connected to the plurality of TSVs, formed on the first surface of the semiconductor substrate.

2. The semiconductor chip of claim 1, wherein only one of the plurality of TSVs is electrically connected to the bonding pad.

3. The semiconductor chip of claim 2, wherein the TSV electrically connected to the bonding pad is electrically connected to the bonding pad through any one of the plurality of fuses.

4. The semiconductor chip of claim 1, wherein the fuse box is exposed through a via hole in the semiconductor substrate.

5. The semiconductor chip of claim 1, wherein the plurality of fuses are exposed through a plurality of holes in the semiconductor substrate.

6. The semiconductor chip of claim 1, further comprising a redistribution layer which connects the bonding pad to the plurality of TSVs.

7. A method for fabricating a semiconductor chip, comprising:
preparing a wafer including a plurality of semiconductor chips, each of which includes: a bonding pad on a first surface of the wafer; and a fuse box including a plurality of fuses connected to the bonding pad;
forming a TSV group including a plurality of TSVs, which are connected to the plurality of fuses, exposed to a second surface opposite to the first surface of the semiconductor substrate; and
performing a repair process to select any one of the plurality of TSVs.

8. The method of claim 7, wherein the forming of the TSV group comprises:
forming an insulation layer, which exposes the bonding pad, on the first surface of the wafer;
attaching the wafer to a carrier to expose the second surface opposite to the first surface of the wafer;
forming a plurality of blind via holes from the second surface of the wafer; and
forming a plurality of TSVs in the plurality of blind via holes.

9. The method of claim 8, wherein the forming of the TSV group further comprises:
forming a via hole exposing the plurality of fuses to the second surface of the wafer.

10. The method of claim 9, wherein the via hole exposes the entire fuse box.

11. The method of claim 9, wherein the forming of the via hole comprises forming a plurality of holes exposing the plurality of fuses separately.

12. The method of claim 9, wherein the forming of the via hole is performed simultaneously with the forming of the blind via holes.

13. The method of claim 9, wherein the repair process is performed by cutting one or more of the plurality of fuses exposed by the via hole.
